(19) United States
(12) Patent Application Publication
(10) Pub. No.: US 2011/0266040 A1
(43) Pub. Date: Nov. 3, 2011

(54) MULTILAYER CERAMIC CAPACITOR, PRINTED CIRCUIT BOARD INCLUDING THE SAME, METHODS OF MANUFACTURING THEREOF

(75) Inventors: Go Eun KIM, Hwaseong (KR); Dong Chun Lim, Yongin (KR); Yong Won Seo, Seoul (KR)

(73) Assignee: SAMSUNG ELECTRO-MECHANICS CO., LTD.

(21) Appl. No.: 13/099,877

(22) Filed: May 3, 2011

(30) Foreign Application Priority Data
May 3, 2010 (KR) 10-2010-0041566

(51) Int. Cl. H05K 1/18; H05K 3/30; H01G 4/228

(52) U.S. Cl. 174/260; 361/306.3; 29/25.41; 29/832

(57) ABSTRACT

There are provided a multilayer ceramic capacitor, a printed circuit board including the same, a method of manufacturing the multilayer ceramic capacitor, and a method of manufacturing the printed circuit board. The method of manufacturing a multilayer ceramic capacitor includes: preparing a capacitor body on which external electrode material layers are formed, dry polishing the capacitor body such that surfaces of the external electrode material layers are smooth and compact, and forming plating layers on the surfaces of the external electrode material layers in order to form external electrodes. Therefore, the surface smoothness, compactness, and uniformity of an external electrode plating layer can be improved.

### CROSS-REFERENCE TO RELATED APPLICATIONS

This application claims the priority of Korean Patent Application No. 10-2010-0041566 filed on May 3, 2010, in the Korean Intellectual Property Office, the disclosure of which is incorporated herein by reference.

### BACKGROUND OF THE INVENTION

1. Field of the Invention

The present invention relates to a multilayer ceramic capacitor, a printed circuit board including the same, and methods of manufacturing thereof, and more particularly, to a multilayer ceramic capacitor having improved surface smoothness, compactness, and uniformity of an external electrode plating layer, a printed circuit board including the same, a method of manufacturing the multilayer ceramic capacitor, and a method of manufacturing the printed circuit board.

2. Description of the Related Art

Compactness, thinness and high capacity have increasingly been required in a chip device, such as a multilayer ceramic capacitor (MLCC), a chip resistor, and a chip inductor, due to the need for the slimness, lightness, and multifunctionality of an electronic product.

In the past, development proceeded in such a manner that a slimmed and miniaturized chip device is printed or mounted on a substrate. However, the development of a substrate having a chip device embedded therein has been actively proceeded in order to reduce even mounting space occupied when the chip device is mounted on the substrate.

A chip device embedded in a substrate has almost the same basic characteristics as the existing chip device, but does not need to be mounted on the substrate. Therefore, a plating process for providing mountability could be omitted. However, instead of omitting the plating process for providing mountability, a special surface treatment on an external electrode is required in order to prevent deterioration in the function of the chip device while the chip device is embedded in the substrate or subsequent thereto.

An embedded chip, on which a surface treatment is not performed, may cause cracks, delamination, damage, or the like thereof, by laser erosion during a laser processing, thus leading to deteriorated characteristics and defects, such as shorts. As the conditions of the external electrodes of the embedded chip needs to be in good state in order to minimize laser erosion, a surface treatment such as polishing or plating needs to maintain the state of the external electrodes.

### SUMMARY OF THE INVENTION

An aspect of the present invention provides a multilayer ceramic capacitor capable of preventing cracking due to the diffusion of electrode materials while securing stable electrostatic capacitance, a printed circuit board including the same, a method of manufacturing the multilayer ceramic capacitor, and a method of manufacturing the printed circuit board.

According to an aspect of the present invention, there is provided a method for manufacturing a multilayer ceramic capacitor, including: preparing a capacitor body on which external electrode material layers are formed; dry polishing the capacitor body such that surfaces of the external electrode material layers are smooth and compact; and forming plating layers on the surfaces of the external electrode material layers in order to form external electrodes.

The dry polishing of the capacitor body may be performed by using ceramic balls.

The ceramic balls may be made of at least one selected from zirconia, alumina, and silicon carbide.

The forming of the plating layers may be performed such that the plating layers have a thickness of 0.5 μm to 20 μm.

The plating layers may be made of copper (Cu) in the forming of the plating layers.

According to another aspect of the present invention, there is provided a multilayer ceramic capacitor, including: a capacitor body, the capacitor body being dry polished such that surfaces of external electrodes thereof are smooth and compact; and plating layers formed on the surfaces of the external electrodes.

The dry polishing may be performed by using ceramic balls.

The ceramic balls may be made of at least one selected from zirconia, alumina, and silicon carbide.

The plating layers may have a thickness of 0.5 μm to 20 μm.

The plating layers may be made of copper (Cu).

According to another aspect of the present invention, there is provided a method for manufacturing an electronic device-embedded printed circuit board, including: preparing a substrate including a concave portion; and embedding a capacitor body in the concave portion of the substrate, the capacitor body including surfaces of external electrode material layers dry polished to be smooth and compact and having plating layers formed thereon.

The capacitor body may be dry polished by using ceramic balls, in the embedding of the capacitor body.

The ceramic balls may be made of at least one selected from zirconia, alumina, and silicon carbide.

The forming of the plating layer may be performed such that the plating layers have a thickness of 0.5 μm to 20 μm, in the embedding of the capacitor body.

The plating layers may be made of copper (Cu), in the embedding of the capacitor body.

The embedding of the capacitor body may further include laser processing for forming a hole exposing the embedded capacitor body to the outside of the substrate after forming the plating layers.

The forming of the hole may be performed by a laser processing method.

According to another aspect of the present invention, there is provided an electronic device-embedded printed circuit board, including: a substrate including a concave portion; and a capacitor body embedded in the concave portion, the capacitor body including surfaces of external electrode material layers dry polished to be smooth and compact and having plating layers formed thereon.

The dry polishing may be performed by using ceramic balls.

The ceramic balls may be made of at least one selected from zirconia, alumina, and silicon carbide.

The plating layers may have a thickness of 0.5 μm to 20 μm.

The plating layers may be made of copper (Cu).

The electronic device-embedded printed circuit board further includes a hole exposing the embedded capacitor body to the outside of the substrate.

The hole may be formed by a laser processing method.

### BRIEF DESCRIPTION OF THE DRAWINGS

FIG. 1 is a perspective view of a multilayer ceramic capacitor according to an embodiment of the present invention;

FIG. 2 is a cross-sectional view of a multilayer ceramic capacitor taken along line A-A′ of FIG. 1;

FIG. 3 is a cross-sectional view of a multilayer ceramic capacitor taken along line B-B′ of FIG. 1;

FIGS. 4A and 4B are cross-sectional views schematically showing principal manufacturing processes of a multilayer ceramic capacitor according to an embodiment of the present invention;

FIGS. 5A to 5C are cross-sectional views schematically showing principal manufacturing processes of an electronic device-embedded printed circuit board according to another embodiment of the present invention;

FIGS. 6A to 6E are images of a capacitor body, a surface of which is dry polished by using zirconia balls, according to example 1 of the present invention;

FIGS. 7A to 7E are images of a capacitor body, a surface of which is not dry polished, according to comparative example 1;

FIGS. 8A to 8E are images of a capacitor body obtained by dry polishing a surface thereof by using zirconia balls and then forming a plating layer made of copper on a surface of an external electrode material layer, according to example 2 of the present invention;

FIGS. 9A to 9D are images of a capacitor body obtained by forming a plating layer made of copper on a surface of an external electrode material layer thereof, without dry polishing a surface of the capacitor body, according to comparative example 2;

FIGS. 10A to 10C are images of a capacitor body obtained by dry polishing a surface thereof, forming a plating layer made of copper on a surface of an external electrode material layer to complete an external electrode, and plating the plating layer with nickel (Ni) and tin (Sn) in order to more precisely observe smoothness of the plating layer, according to example 3 of the present invention;

FIGS. 11A to 11C are images of a capacitor body obtained by forming a plating layer made of copper on a surface of an external electrode material layer, and plating the plating layer with nickel (Ni) and tin (Sn) in order to more precisely observe the smoothness of the plating layer, without dry polishing a surface of the capacitor body, according to comparative example 3; and

FIGS. 12A to 15C are images of an electronic device-embedded printed circuit board having a capacitor body embedded in a concave portion thereof, the capacitor body obtained by dry polishing a surface thereof and forming a plating layer made of copper on a surface of an external electrode material layer thereof, according to example 4 of the present invention.

### DETAILED DESCRIPTION OF THE PREFERRED EMBODIMENT

Hereinafter, exemplary embodiments of the present invention will now be described in detail in accordance with the accompanying drawings. In the drawings, the same reference numerals will be used throughout to designate the same or like elements. Also, detail descriptions with regard to well known functions and configurations, which may obscure the substance of the present invention, will be omitted.

like reference numerals denote parts performing similar functions and actions throughout the drawings. In addition, throughout the specification, when an element is referred to as being “connected” to another element, this includes being “directly connected” as well as being “indirectly connected” to another element with the other element interposed therebetwen. Also, the word “comprising” a certain element, unless explicitly described to the contrary, implies the further inclusion of other elements but not the exclusion of other elements.

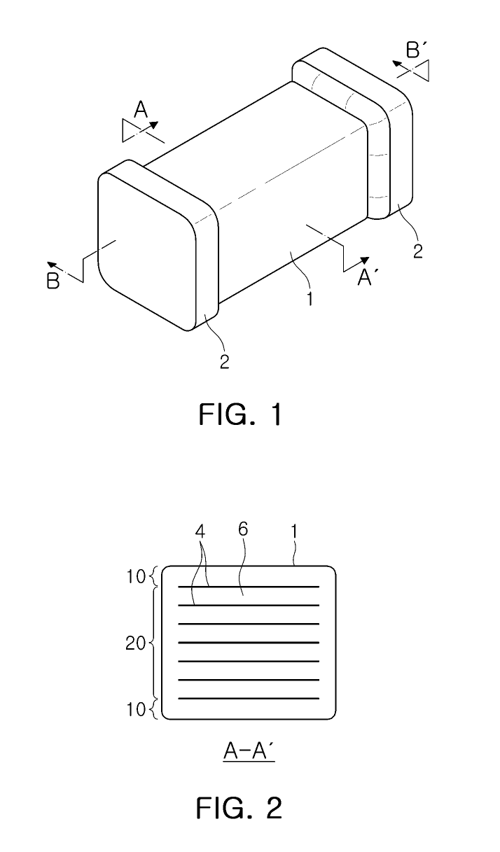

Hereinafter, referring to FIGS. 1 to 5C, it will be described with respect to principal manufacturing processes of a multilayer ceramic capacitor and principal manufacturing process of an electronic device-embedded printed circuit board according to embodiments of the present invention.

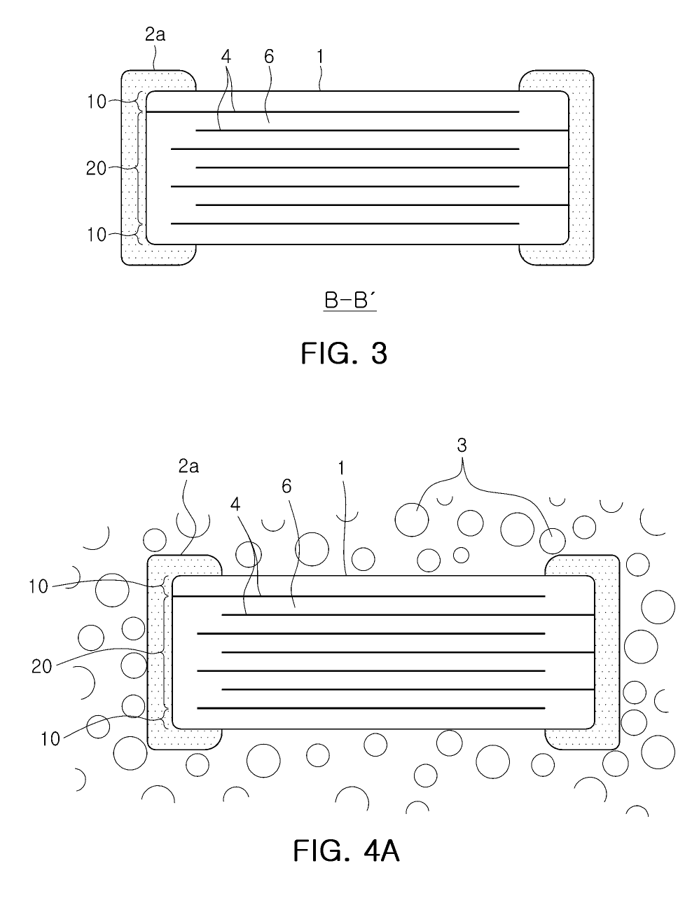

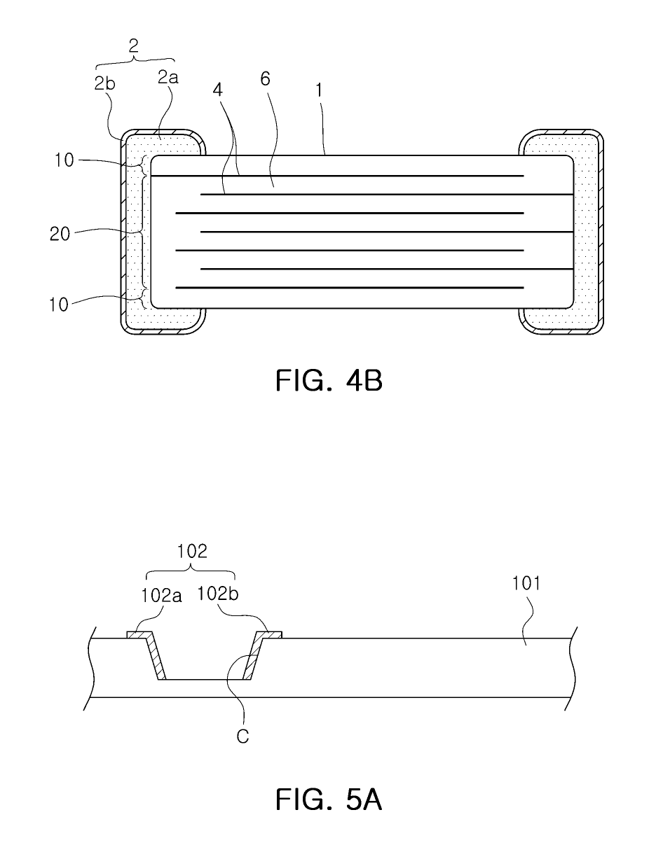

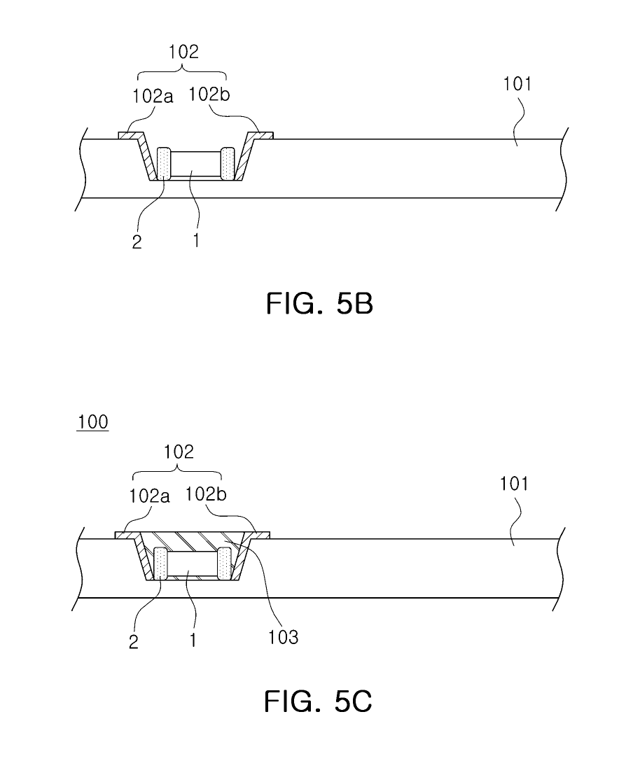

FIG. 1 is a perspective view of a multilayer ceramic capacitor according to an embodiment of the present invention. FIG. 2 is a cross-sectional view of a multilayer ceramic capacitor taken along line A-A′ of FIG. 1. FIG. 3 is a cross-sectional view of a multilayer ceramic capacitor taken along line B-B′ of FIG. 1. FIGS. 4A and 4B are cross-sectional views schematically showing principal manufacturing processes of a multilayer ceramic capacitor according to an embodiment of the present invention. FIGS. 5A to 5C are cross-sectional views schematically showing principal manufacturing processes of an electronic device-embedded printed circuit board according to another embodiment of the present invention.

A multilayer ceramic capacitor according to an embodiment of the present invention may include a capacitor body 1, external electrodes 2, and plating layers (not shown).

The capacitor body 1 may have a plurality of dielectric layers 6 laminated therein, and internal electrodes 4 inserted between the plurality of dielectric layers 6. Herein, the dielectric layers 6 may be formed by using barium titanate (BaTiO₃).

The internal electrodes 4 may be formed of an electrode material including nickel (Ni) or nickel (Ni) alloy. The external electrodes 2 are formed on external end surfaces of the capacitor body 1, and electrically connected to the internal electrodes 4. Each of the external electrodes 2 is formed of an external electrode material layer 2a including copper (Cu) or Copper (Cu) alloy and a plating layer 2b formed on a surface of the external electrode material layer 2a. The external electrodes 2 are formed to be electrically connected to the internal electrodes 4 which are exposed to the end surfaces of the capacitor body 1, thereby functioning as external terminals.

The multilayer ceramic capacitor according to an exemplary embodiment of the present embodiment may include an effective layer 20 in which the dielectric layers 6 and the internal electrodes 4 are alternately laminated. Also, the multilayer ceramic capacitor may further include protective layers 10 formed on an upper surface and a lower surface of the effective surface 20. Each of the protective layers 10 may be formed by laminating dielectric layers.

The protective layers 10 are formed by sequentially laminating a plurality of dielectric layers on the upper surface and the lower surface of the effective layer 20, thereby protecting the effective layer 20 from outside impact.

The surfaces of external electrodes 2 of the multilayer ceramic capacitor according to an exemplary embodiment of the present embodiment are dry polished such that the surfaces of the external electrodes are smooth and compact. Then, the plating layers (not shown) are formed on the dry polished surfaces of the external electrodes 2.

Herein, the dry polishing is performed by using ceramic balls. The ceramic ball may be made of at least one selected from zirconia, alumina, and silicon carbide, but not limited thereto. In an exemplary embodiment of the present embodiment, by way of example, a case in which zirconia is used for the ceramic balls, as used in the dry polishing will be explained.

The plating layer may have a thickness of 0.5 μm to 20 μm. When the thickness of the plating layer is less than 0.5 μm, cracks, delamination, damage, and defective characteristics are caused in the substrate or the ceramic capacitor, due to laser processing. When the thickness of the plating layer is more than 20 μm, the entire thickness of a chip becomes thicker, thereby causing defects such as short circuits with a layer above the chip when the chip is embedded in the substrate. The plating layer may consist of copper (Cu).

### Example 1

As shown in FIG. 4A, dielectric layers 6 of a capacitor body 1 were formed to include a binder, a plasticizer, and a residual dielectric material. The dielectric layers 6 were obtained by molding slurry including the constituent materials. Conductive internal electrodes 4 including nickel were printed on the dielectric layers 6, respectively. Then, the printed dielectric layers 6 were used to manufacture a lamination body having a predetermined thickness.

Next, the external electrode material layers 2a including copper were formed on the capacitor body 1. Then, the capacitor body 1 was dry polished by using zirconia ceramic balls 3. As a result, the surfaces of the external electrode material layers 2a became smooth and compact. Herein, the ceramic balls may be made of at least one selected from zirconia, alumina, and silicon carbide, but a material for forming the ceramic balls 3 is not limited thereto.

### Example 2

As in the example 1, a capacitor body 1, of which the surface was dry polished by using zirconia balls 3, was manufactured. Then, as shown in FIG. 4B, external electrodes 2 were completed by respectively forming plating layers 2b made of copper on the surfaces of external electrode material layers 2a which had been dry polished by zirconial balls 3 to be smooth and compact. Herein, the plating layers 2b made of copper were formed to have a thickness of 10 μm. The plating layers 2b were made of copper (Cu).

### Example 3

As in the example 2, external electrodes 2 werecompleted by respectively forming plating layers 2b made of copper on the surfaces of external electrode material layers 2a of a capacitor body 1, of which the surface was dry polished. Then, the plating layers 2b were plated with nickel (Ni) and tin (Sn) in order to more precisely observe the smoothness thereof.

### Example 4

As shown in FIG. 5A, a substrate 101 having a concave portion C was prepared. Then, a wiring layer 102 including a first wiring layer 102a and a second wiring layer 102b was formed. Herein, the concave portion C and the wiring layer 102 were formed by a photolithography process, but not limited thereto.

Next, as shown in FIG. 5B, the capacitor body 1 formed in the example 1 was embedded in the concave portion C of the substrate 101. The dielectric layers 6 (see, FIG. 3) were formed to include a binder, a plasticizer, and a residual dielectric material. As for the capacitor body 1, the surfaces of external electrode materials 2a were dry polished by the zirconia ceramic balls 3 to be smooth and compact, and then the plating layers 2b made of copper were formed on the surfaces of the external electrode material layers 2a, thereby completing the external electrodes 2. Then, the capacitor body 1 was subjected to laser processing in order to connect the substrate 101 and a chip, thereby allowing electrical conduction therebetween.

Herein, as described above, the degree of laser processing and the precision of laser processing may be varied according to the surface smoothness, uniformity, and thickness of the plating layers 2a of the capacitor body 1 embedded in the concave portion C of the substrate 101. Cracks or delamination may occur, or damage or characteristic defects may arise in the capacitor body 1 and the substrate 101 according to the degree of laser processing and the precision of laser processing. However, according to the example of the present embodiment, as dry polishing is performed on the surfaces of the external electrode material layers 2a by using the zirconia ceramic balls 3 before the plating layers 2a of the capacitor body 1 are formed thereon, the surfaces of the external electrode material layers 2a become smooth and compact. Consequently, the surfaces of the plating layers 2a are also flat, compact, and smooth, and thereby have a uniform thickness.

Next, as shown in FIG. 5C, an insulating layer 103 exposing portions of the first wiring layer 102a and the second wiring layer 102b was formed on the capacitor body 1 embedded in the concave portion C of the substrate 101, thereby completing an electronic device-embedded printed circuit board 100.

### Comparative Example 1

A capacitor body 1 was manufactured in the same manner as in the example 1, except for dry polishing the surface of the capacitor body 1 by using the zirconia balls 3.

### Comparative Example 2

A capacitor body 1 was manufactured in the same manner as in the example 2, except for dry polishing the surface of the capacitor body 1 by using the zirconia balls 3, and then plating layers 2b made of copper were formed on the surfaces of external electrode material layers 2a.

### Comparative Example 3

A capacitor body 1 was manufactured in the same manner as in the example 3, except for dry polishing the surface of the capacitor body 1 by using the zirconia balls 3, and then plating layers 2b made of copper were formed on the surfaces of external electrode material layers 2a. Next, the plate layers 2b were plated with nickel (Ni) and tin (Sn) in order to more precisely observe the smoothness thereof.

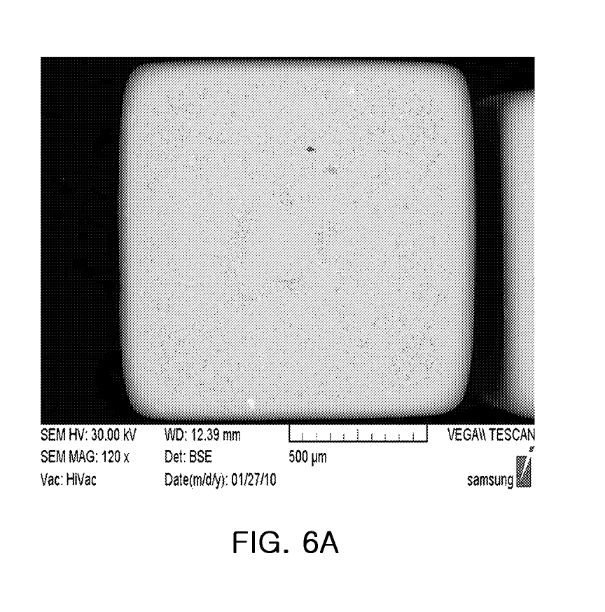

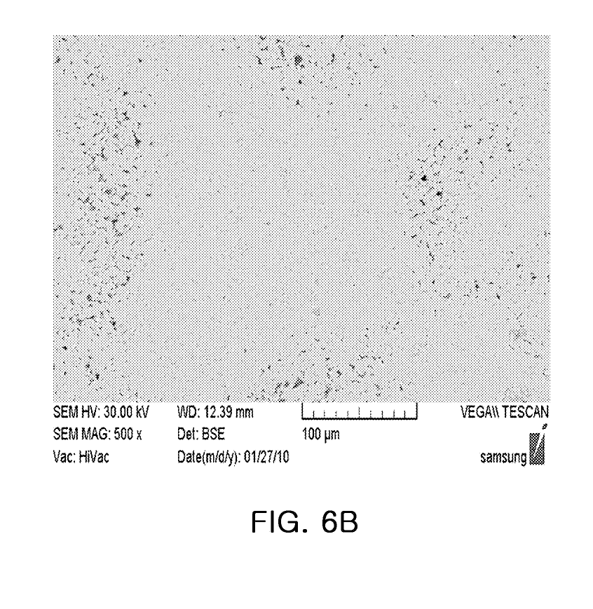

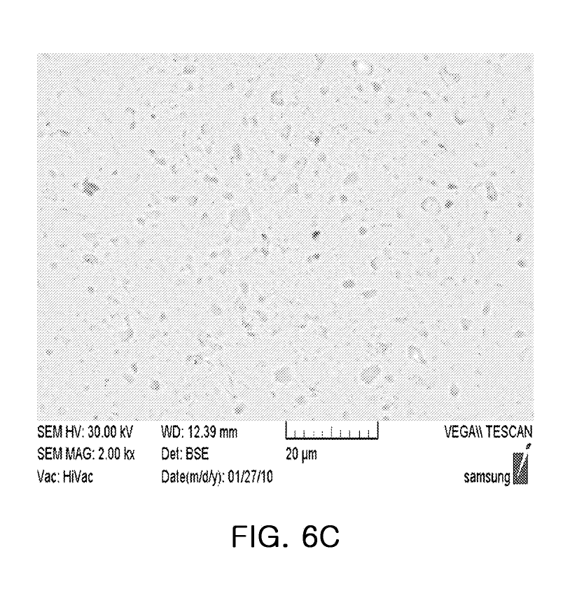

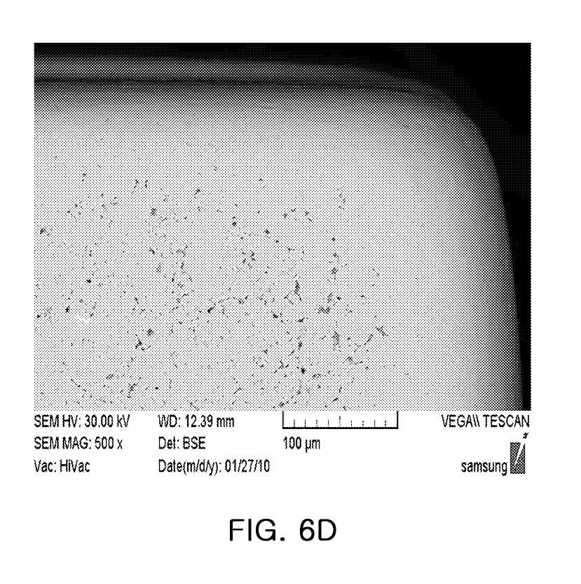

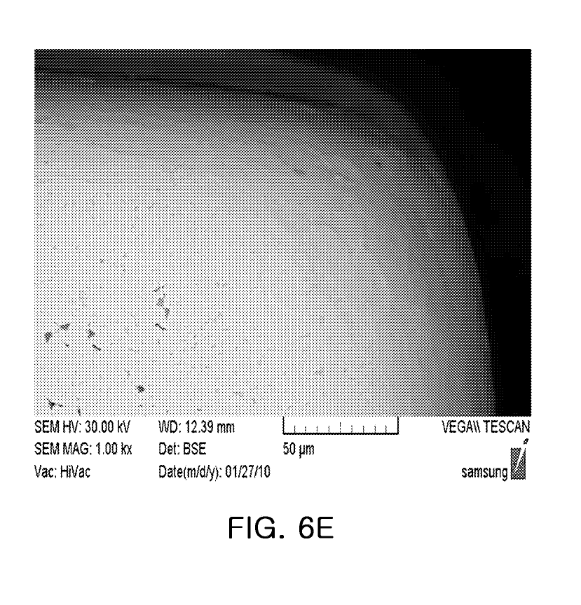

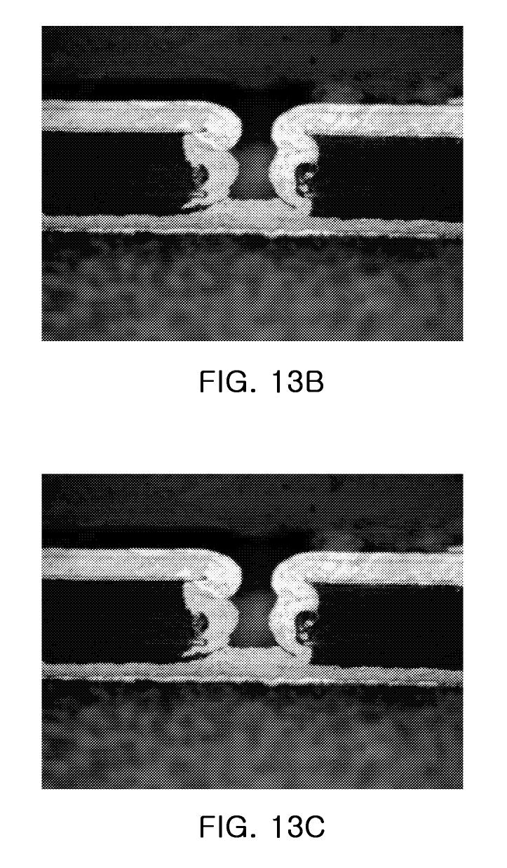

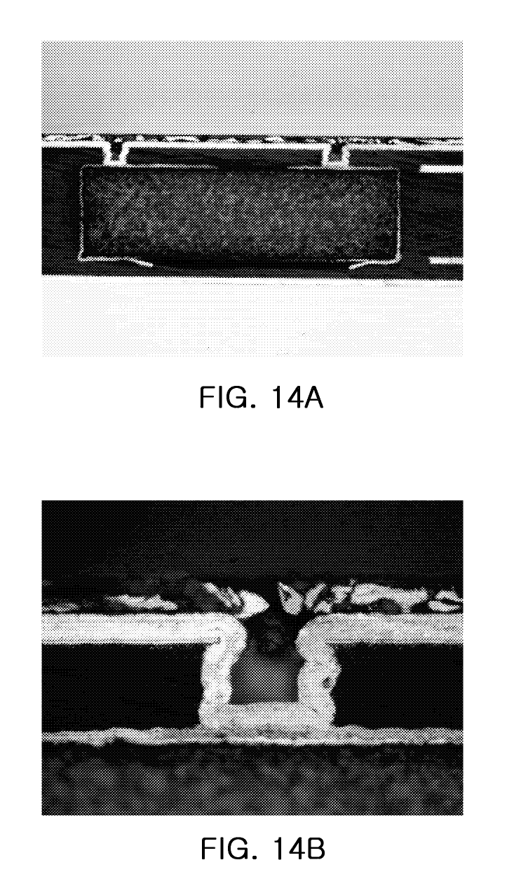

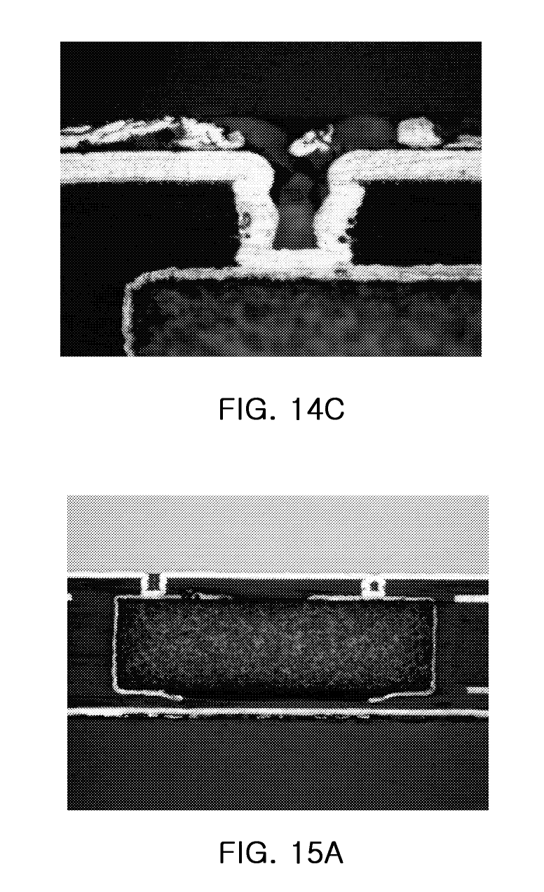

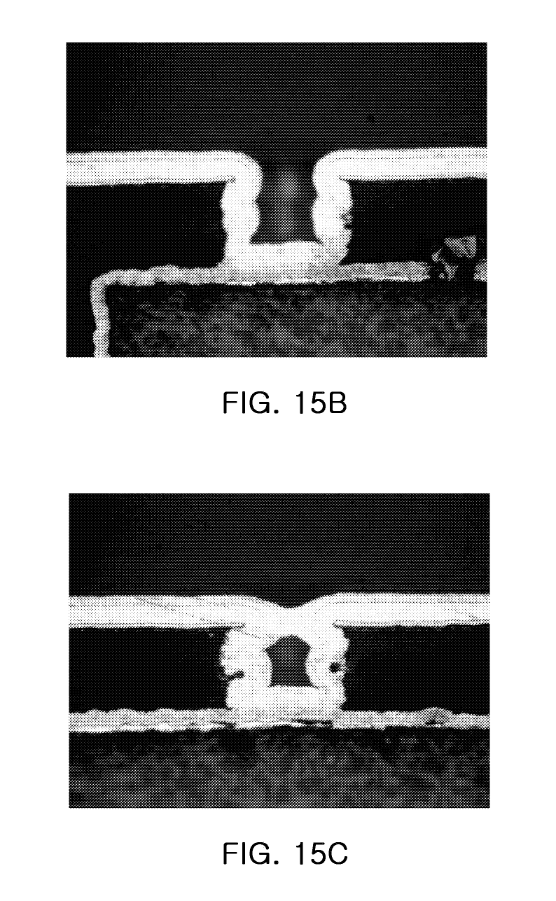

Hereinafter, the example 1 to the example 3 according to the present invention and the comparative example 1 to the comparative example 3 will be described, with reference to images of FIGS. 6A to 15C.

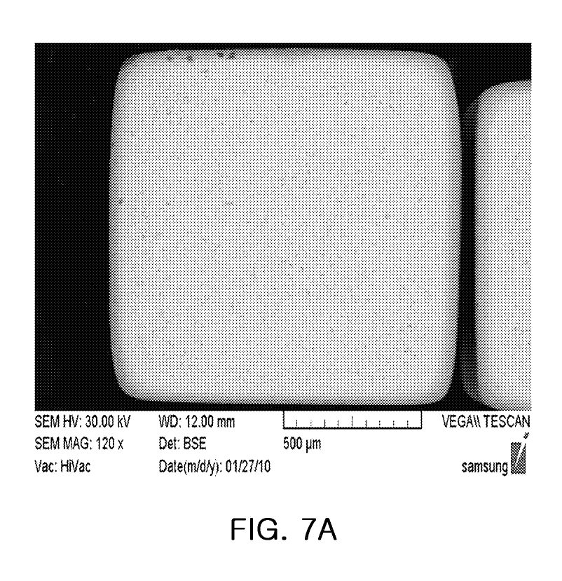

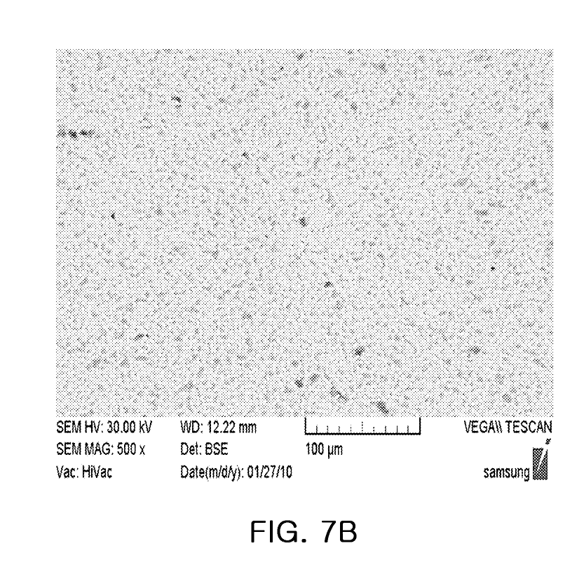

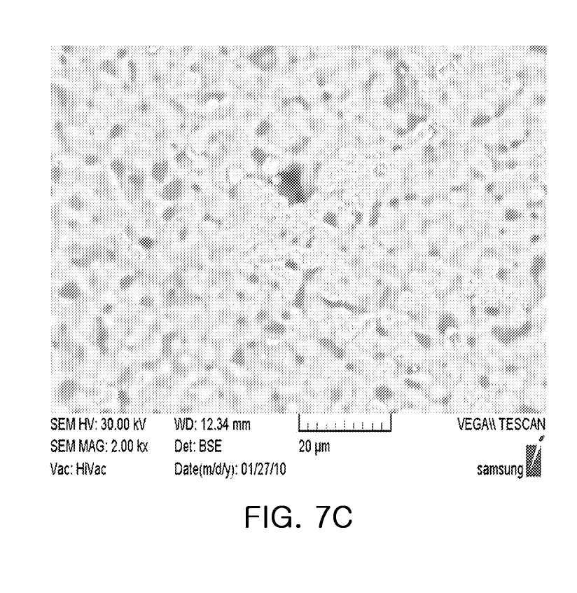

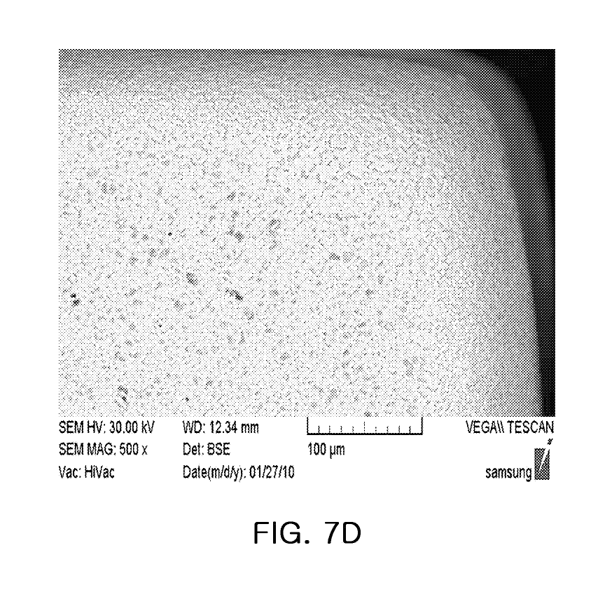

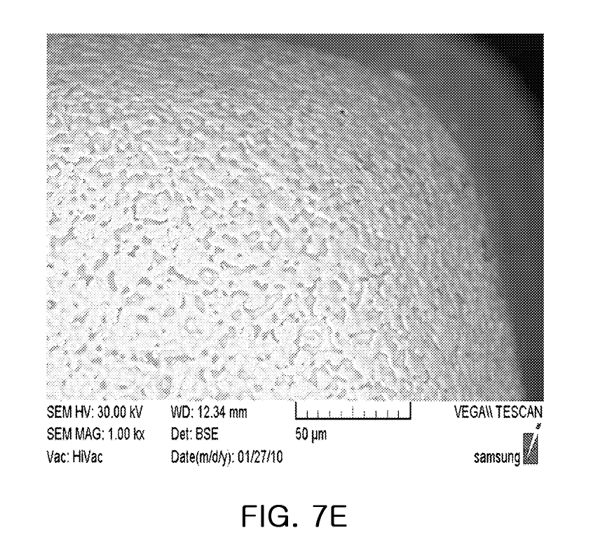

FIGS. 6A to 6E are images of a capacitor body 1, a surface of which is dry polished by using zirconia balls 3, according to the example 1 of the present invention; and FIGS. 7A to 7E are images of a capacitor body 1, a surface of which is not dry polished, according to the comparative example 1.

As can be seen in FIGS. 6A to 7E, a surface of the capacitor body 1, which is dry polished by using the zirconia balls 3 has uniform compactness and smoothness as compared with a surface of the capacitor body 1 which is not dry polished.

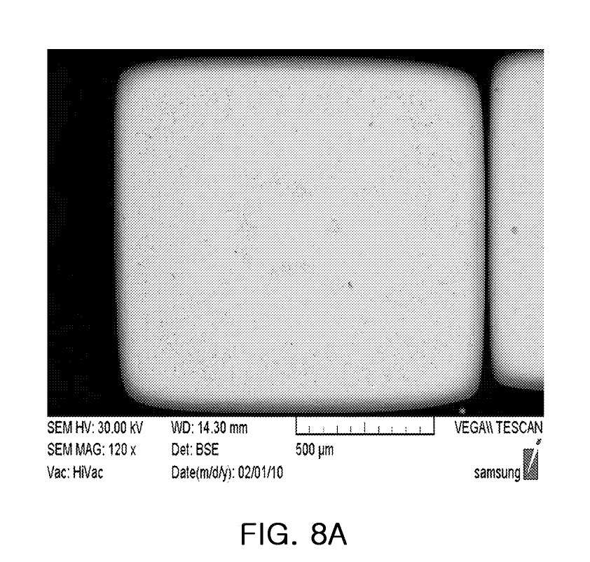

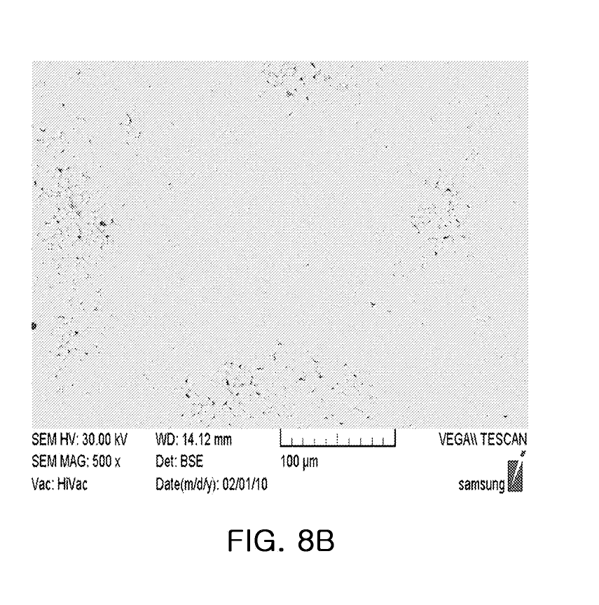

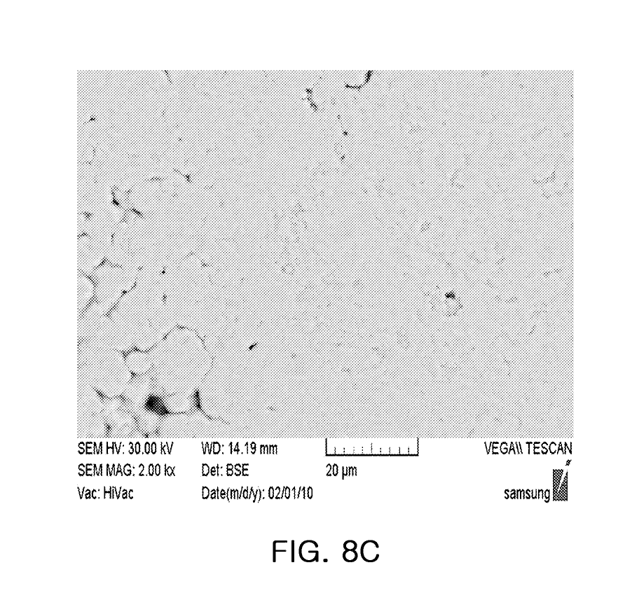

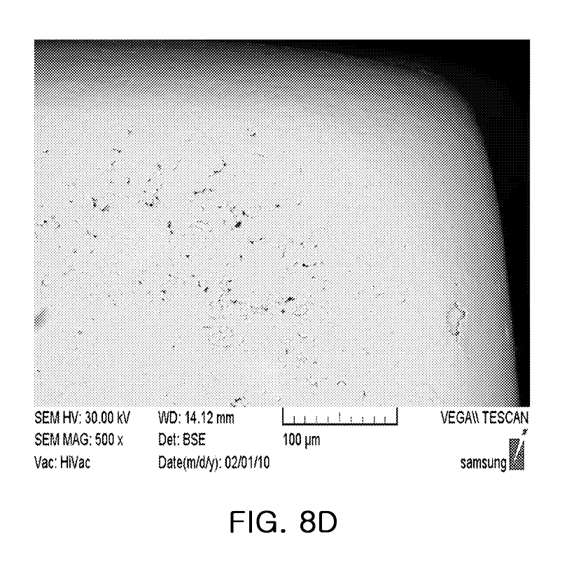

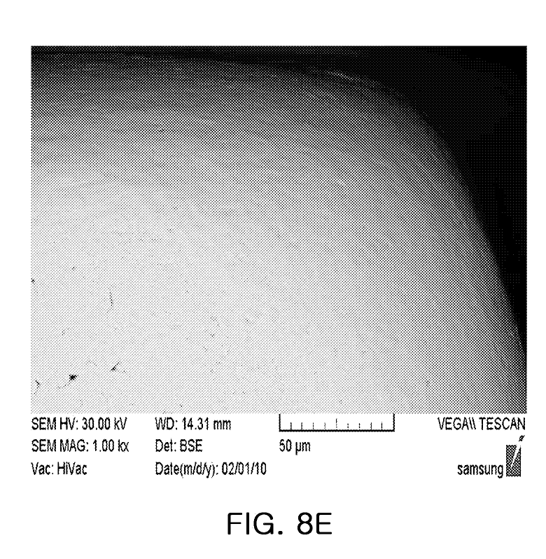

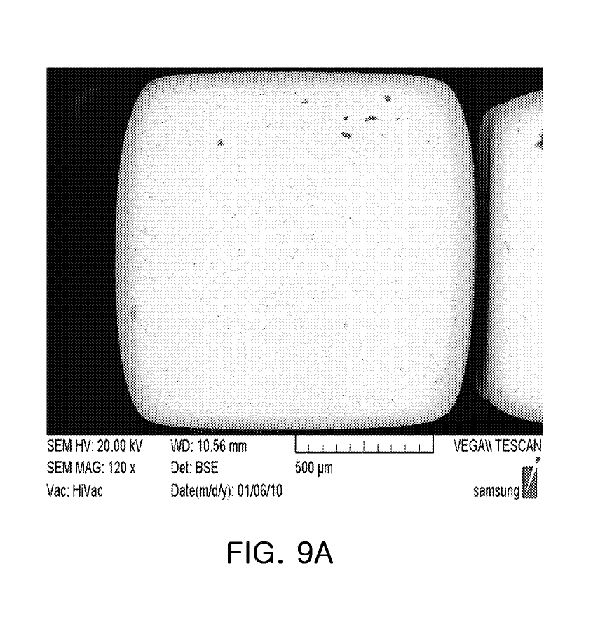

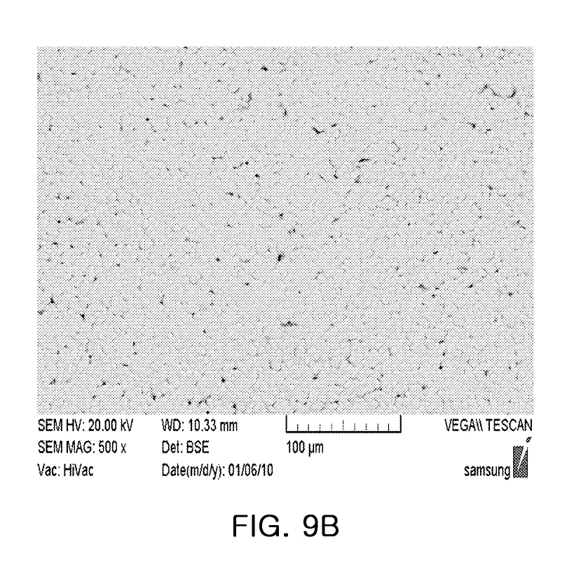

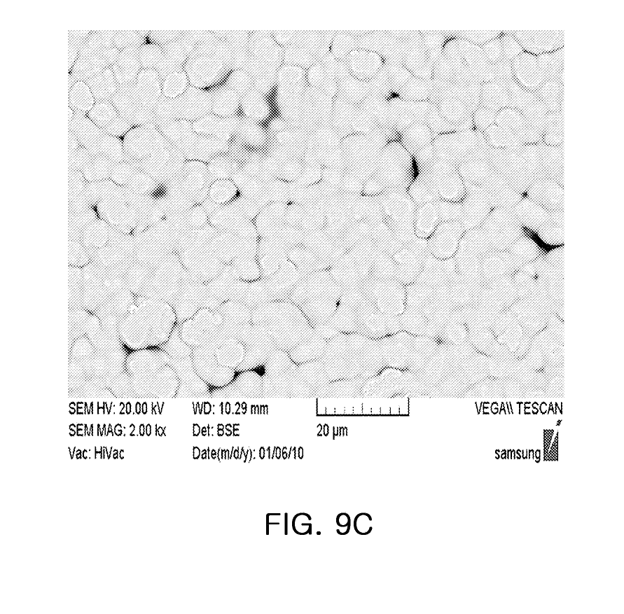

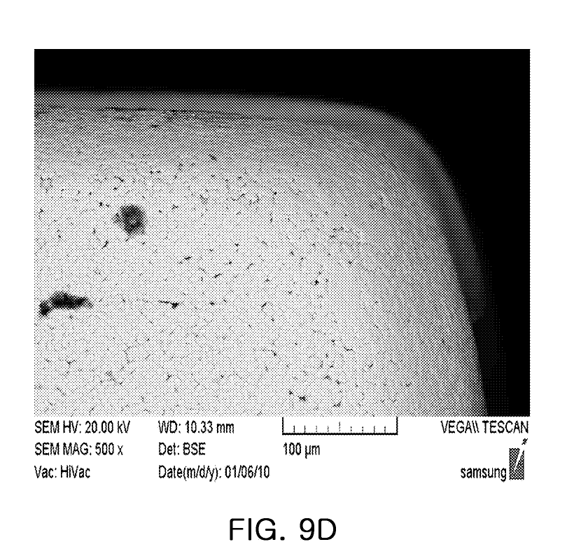

FIGS. 8A to 8E are images of a capacitor body 1 obtained by dry polishing a surface thereof by using zirconia balls 3 and then forming a plating layer 2b made of copper on a surface of an external electrode material layer 2a, according to the example 2 of the present invention; and FIGS. 9A to 9D are images of a capacitor body 1 obtained by forming a plating layer 2b made of copper on a surface of an external electrode material layer 2a, without dry polishing a surface of the capacitor body 1, according to the comparative example 2.

As can be seen in images of FIGS. 8A to 9D, a surface of the capacitor body 1 obtained by performing dry polishing thereon by using the zirconia balls 3 and then forming a plating layer 2b made of copper thereon has uniform compactness and smoothness, as compared to a surface of the capacitor body 1 obtained by forming a plating layer 2b made of copper thereon, without performing dry polishing thereon.

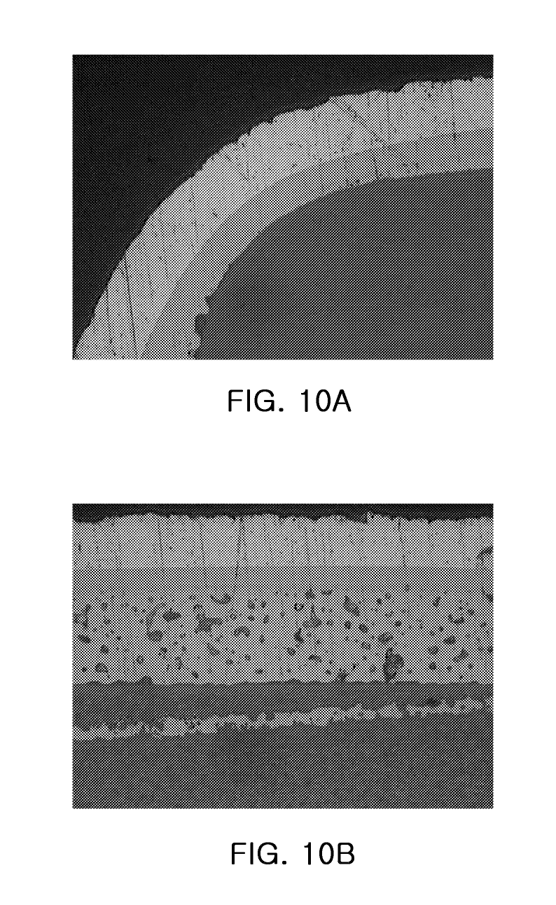

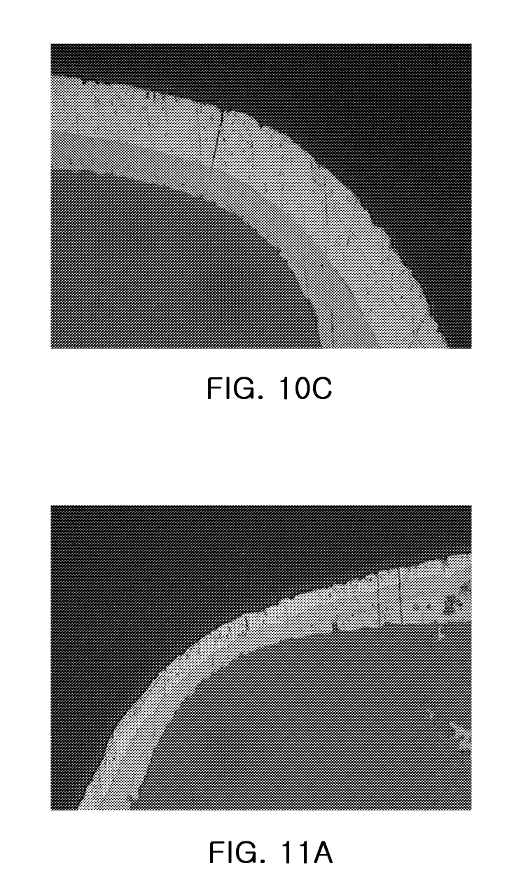

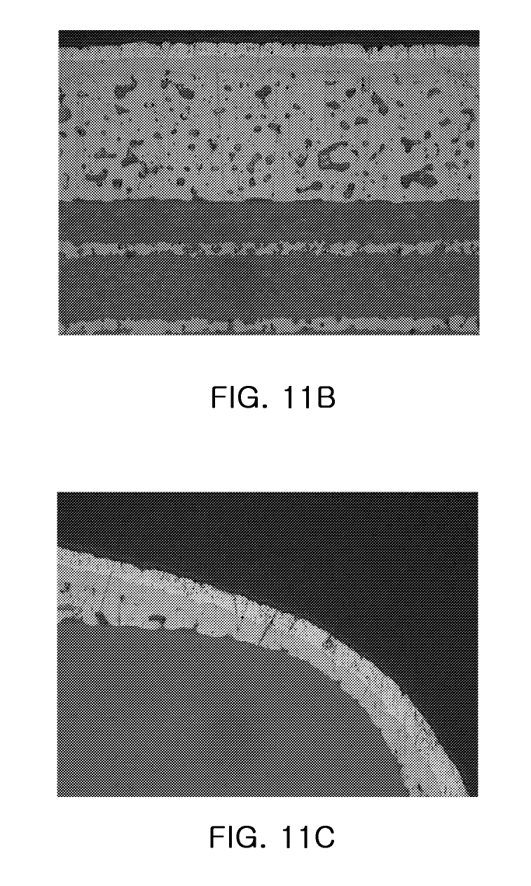

FIGS. 10A to 10C are images of a capacitor body 1 obtained by dry polishing a surface thereof, forming a plating layer 2b made of copper on a surface of an external electrode material layer 2a thereof to complete an external electrode 2, and plating the plating layer 2b with nickel (Ni) and tin (Sn) in order to more precisely observe the smoothness of the plating layer, according to the example 3 of the present invention. FIGS. 11A to 11C are images of a capacitor body 1 obtained by forming a plating layer 2b made of copper on a surface of an external electrode material layer 2a thereof, and plating the plating layer 2b with nickel (Ni) and tin (Sn) in order to more precisely observe the smoothness of the plating layer, without dry polishing the surface of capacitor body 1, according to the comparative example 3.

As can be seen in images of FIGS. 10A to 11C, a surface of the capacitor body 1 obtained by performing dry polishing thereon by using the zirconia balls 3, then forming a plating layer 2b made of copper thereon, and then plating the plating layer 2b with nickel (Ni) and tin (Sn), has uniform compactness and smoothness, as compared to a surface of the capacitor body 1 obtained by forming a plating layer 2b made of copper thereon and then plating the plating layer 2b with nickel (Ni) and tin (Sn), without performing dry polishing on the surface of the capacitor body 1.

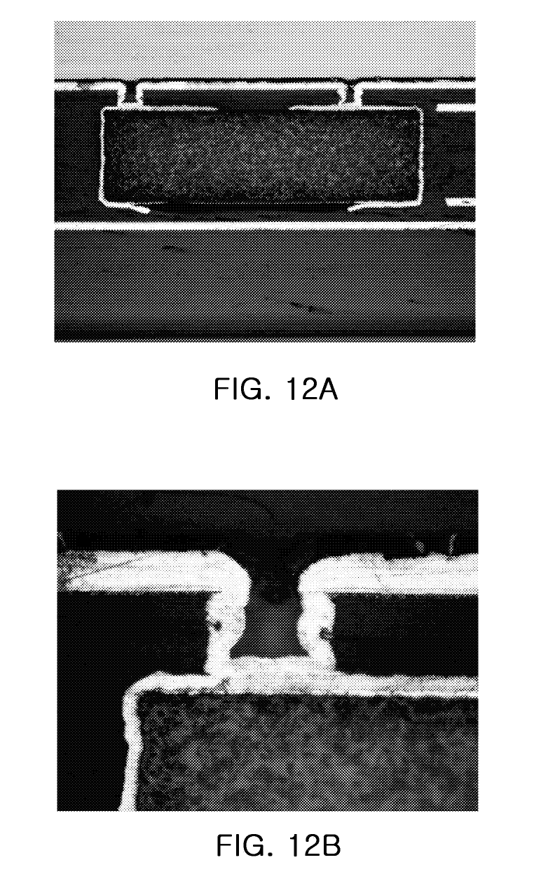

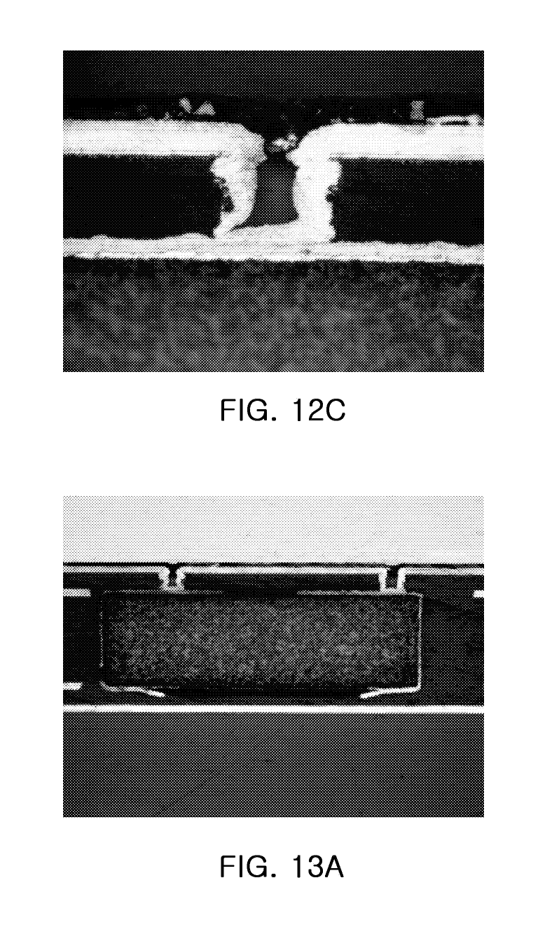

FIGS. 12A to 15C are images of an electronic device-embedded printed circuit board 101 having a capacitor body embedded in a concave portion (c) thereof, the capacitor body obtained by dry polishing a surface thereof and forming a plating layer 2b made of copper on a surface of an external electrode material layer 2a thereof, according to example 4 of the present invention.

As can be seen in FIGS. 12A to 15C, in the printed circuit board 101 in which a capacitor body 1 obtained by dry polishing a surface thereof and forming a plating layer 2b made of copper on a surface of an external electrode material layer 2a thereof is embedded, the surface smoothness, compactness, and uniformity of the plating layer 2b could be improved. Consequently, cracks, delamination, damage, or the like, are not observed in the printed circuit board 101 and the multilayer ceramic capacitor due to laser processing after the capacitor are embedded in the printed circuit board 101.

According to the embodiments of the present invention, there is provided a method of manufacturing a multilayer ceramic capacitor capable of improving the surface smoothness, compactness, and uniformity of an external electrode plating layer.

Further, cracks, delamination, damage, and characteristic defects caused in a printed circuit board and a multilayer ceramic capacitor due to laser processing after the capacitor is embedded in the printed circuit board could be prevented by improving the surface smoothness, compactness, and uniformity of an external electrode plating layer of the multilayer ceramic capacitor.

The present invention is not limited by the above-described embodiments and the accompanying drawings. It will be apparent to those skilled in the art to which the present invention pertains that constituent elements of the present invention can be changed or modified within the range of technical spirits of the invention.

What is claimed is:

1. A method for manufacturing a multilayer ceramic capacitor, comprising:
preparing a capacitor body on which external electrode material layers are formed;
dry polishing the capacitor body such that surfaces of the external electrode material layers are smooth and compact; and
forming plating layers on the surfaces of the external electrode material layers in order to form external electrodes.

2. The method of claim 1, wherein the dry polishing of the capacitor body is performed by using ceramic balls.

3. The method of claim 2, wherein the ceramic balls are made of at least one selected from zirconia, alumina, and silicon carbide.

4. The method of claim 1, wherein the forming of the plating layers is performed such that the plating layers have a thickness of 0.5 μm to 20 μm.

5. The method of claim 1, wherein the plating layers are made of copper (Cu), in the forming of the plating layers.

6. A multilayer ceramic capacitor, comprising:
a capacitor body, the capacitor body being dry polished such that surfaces of external electrodes thereof are smooth and compact; and
plating layers formed on the surfaces of the external electrodes.

7. The multilayer ceramic capacitor of claim 6, wherein the dry polishing is performed by using ceramic balls.

8. The multilayer ceramic capacitor of claim 7, wherein the ceramic balls are made of at least one selected from zirconia, alumina, and silicon carbide.

9. The multilayer ceramic capacitor of claim 6, wherein the plating layers have a thickness of 0.5 μm to 20 μm.

10. The multilayer ceramic capacitor of claim 6, wherein the plating layers are made of copper (Cu).

11. A method for manufacturing an electronic device-embedded printed circuit board, comprising:
preparing a substrate including a concave portion; and
embedding a capacitor body in the concave portion of the substrate, the capacitor body including surfaces of external electrode material layers dry polished to be smooth and compact and having plating layers formed thereon.

12. The method of claim 11, wherein the capacitor body is dry polished by using ceramic balls, in the embedding of the capacitor body.

13. The method of claim 12, wherein the ceramic balls are made of at least one selected from zirconia, alumina, and silicon carbide.

14. The method of claim 11, wherein the forming of the plating layer is performed such that the plating layers have a thickness of 0.5 μm to 20 μm, in the embedding of the capacitor body.

15. The method of claim 11, wherein the plating layers are made of copper (Cu), in the embedding of the capacitor body.

16. The method of claim 11, the embedding of the capacitor body further includes laser processing for forming a hole exposing the embedded capacitor body to the outside of the substrate after forming the plating layers.

17. The method of claim 16, wherein the forming of the hole is performed by a laser processing method.

18. An electronic device-embedded printed circuit board, comprising:
a substrate including a concave portion; and
a capacitor body embedded in the concave portion, the capacitor body including surfaces of external electrode material layers dry polished to be smooth and compact and having plating layers formed thereon.

19. The electronic device-embedded printed circuit board of claim 18, wherein the dry polishing is performed by using ceramic balls.

20. The electronic device-embedded printed circuit board of claim 19, wherein the ceramic balls are made of at least one selected from zirconia, alumina, and silicon carbide.

21. The electronic device-embedded printed circuit board of claim 18, wherein the plating layers have a thickness of 0.5 μm to 20 μm.

22. The electronic device-embedded printed circuit board of claim 18, wherein the plating layers are made of copper (Cu).

23. The electronic device-embedded printed circuit board of claim 18, further comprises a hole exposing the embedded capacitor body to the outside of the substrate.

24. The electronic device-embedded printed circuit board of claim 23, wherein the hole is formed by a laser processing method.
